(19) United States
(12) Patent Application Publication
(10) Pub. No.: US 2011/0095328 A1
(43) Pub. Date: Apr. 28, 2011

(54) CLOSE PROXIMITY COLLIMATOR FOR LED

(75) Inventors: Jan De Graaf, Eindhoven (NL); Martinus Petrus Joseph Peeters, Eindhoven (NL); Elvira Johanna Maria Paulussen, Eindhoven (NL); Daniel Anton Benoy, Eindhoven (NL); Marcellus Jacobus Johannes Van Der Lubbe, Eindhoven (NL); George Hubert Borel, Eindhoven (NL); Mark Eduard Johan Sipkes, Eindhoven (NL); Christoph Gerard August Hoelen, Eindhoven (NL)

(73) Assignee: Koninklijke Philips Electronics N.V., Eindhoven (NL)

(21) Appl. No.: 13/000,038

(22) PCT Filed: Jun. 24, 2009
(86) PCT No.: PCT/IB2009/052718

§ 371 Date: Dec. 20, 2010

(30) Foreign Application Priority Data
Jul. 1, 2008 (EP) 08159402.0

(51) Int. Cl. H01L 33/58

(52) U.S. Cl. 257/98; 438/29; 257/E33.068

(57) ABSTRACT

A method for the manufacture of a light emitting device is provided. The method comprises the steps of: providing a substrate (102) on which at least one light emitting diode (101) is arranged and; arranging a collimator (103), at least partly laterally surrounding said at least one light emitting diode, by bonding said collimator to said at least one light emitting diode and said substrate using a transmissive bonding material (104). By using the inventive method, the collimator can be arranged after the placement of the LED, which facilitates the placement of the LED.

### FIELD OF THE INVENTION

The present invention relates to a light emitting device comprising at least one light emitting diode arranged on a substrate and a collimator at least partly laterally surrounding said at least one light emitting diode for collimating light emitted by said at least one light emitting diode. The present invention further relates to a method for the manufacture of a light emitting device.

### BACKGROUND OF THE INVENTION

Light-emitting devices according to the above field of invention are known conventionally. They are used as light sources, inter alia, in backlight-emitting panels in (picture) display devices, for example for TV sets and monitors. Such devices are particularly suitable for use as light sources in backlights for non-emissive displays such as liquid crystal display devices, also denoted LCD panels, which are used in (portable) computers or (portable) telephones.

Such devices are also used as light sources in luminaires for general lighting purposes or for shop lighting, for example shop window lighting or lighting of (transparent or semi-transparent) plates of glass or of (transparent) plates of glass or of (transparent) synthetic resin on which items, for example jewelry, are displayed. Such devices are further used as light sources for window panes, for example for causing a glass wall to radiate light under certain conditions, or to reduce or block out the view through the window by means of light. A further alternative application is the use of such devices packages as light sources for illuminating advertising boards. In addition, the devices packages can be used for interior lighting, in particular for home lighting.

A light emitting device of this type is described in WO 2005/109529, where a light emitting diode is arranged on a substrate and within a collimator of a ceramic material.

The approach in WO2005/109529 however typically requires that the LED-chip is mounted in the preformed ceramic collimating structure on the substrate.

Hence, there exists a need for an improved light emitting device that is more easily manufactured.

### SUMMARY OF THE INVENTION

It is an object of the present invention to at least partly overcome this problem, and to provide a light emitting device where the collimating structure easily can be arranged after the light emitting diode has been arranged on the substrate.

In a first aspect, the present invention relates to a method for the manufacture of a light emitting device comprising the steps of:
providing a substrate on which at least one light emitting diode is arranged;
arranging a collimator, at least partly laterally surrounding said at least one light emitting diode, by bonding said collimator to said at least one light emitting diode and said substrate using a transmissive bonding material.

By using the inventive method, the collimator can be arranged after the placement of the LED, which facilitates the placement of the LED.

In embodiments of the present invention a self-supporting wavelength converting element is optically and physically bonded to a light emitting surface of said at least one light emitting diode.

LEDs with wavelength converting plates emit a large portion of the light in directions at an high angle to the normal of the substrate. Hence, the use of collimator is much advantageous for such applications.

In embodiments of the present invention, the step of bonding said collimator to said at least one light emitting diode and said substrate comprises arranging a bonding material precursor and hardening this to form a bonding material.

A liquid bonding material can easily be dispensed, etc, while allowing a certain degree of movement, e.g. adjustment, of the position of the collimator.

In embodiment of the present invention said collimator is arranged at a distance of from 10 to 200 μm, in the plane of said substrate, from said at least one light emitting diode.

The collimator is advantageously positioned close to the LED in order to maintain or minimized the loss in etendue.

In embodiments of the invention, said collimator is formed from a metallic material.

Collimators made of metallic material may be produced to be very thin while having a high reflection efficiency. Hence, they are suitable to use in the approach where the collimator is glued to the substrate.

In embodiments of the present invention, the collimator is formed by at least one self-supporting wall element with a material thickness in the range of 100 to 500 μm.

In a second aspect, the present invention relates to a light emitting device comprising at least one light emitting diode arranged on a substrate and a collimator at least partly laterally surrounding said at least one light emitting diode for collimating light emitted by said at least one light emitting diode. Here, the collimator is bonded to said substrate and to said at least one light emitting diode by means of a first transmissive bonding material. It is further to be noted that the present invention relates to all possible combinations of the appended claims.

### BRIEF DESCRIPTION OF THE DRAWINGS

These and other aspects of the present invention will now be described in more detail, with reference to the appended drawings showing a currently preferred embodiment of the invention.

FIG. 1 illustrates schematically a method for the manufacture of a light emitting device.

### DETAILED DESCRIPTION

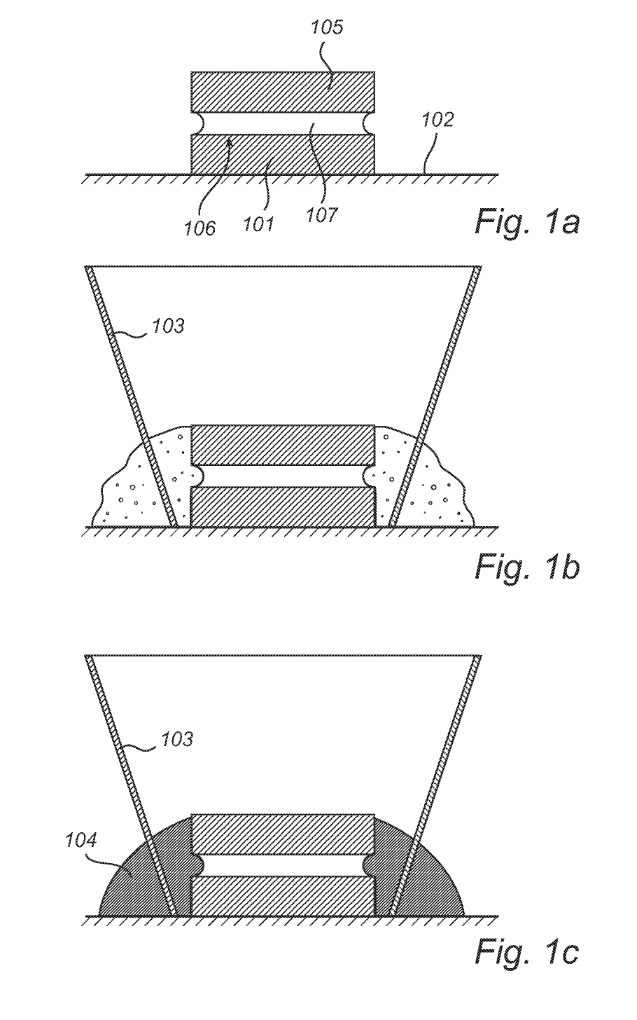

An illustrative embodiment of a device of the present invention is illustrated in FIG. 1. The light emitting device 100 of this embodiment comprises a light emitting diode (LED) chip 101 arranged on a substrate 102. A self-supporting wavelength converting body 105 is optically and physically bonded to a light emitting surface 106 of the diode 101 by means of a transmissive bonding material 107.

The light emitting diode 101 emits light, mainly through its light emitting surface, of a first wavelength (or a first wavelength interval with a first peak intensity).

The wavelength converting body 105 is adapted to receive and absorb at least part of the light emitted by the diode 101 and to convert the absorbed light into light of a second, higher wavelength (or a second wavelength interval with a peak intensity at a higher wavelength). The wavelength conversion is due to wavelength converting materials, such as fluorescent and/or phosphorescent materials contained in the wavelength converting body.

The LED-chip 101 is typically connected to conductive lines (not shown) for driving the LED chip.

The light emitted by the LED and/or converted in by the wavelength converting material is collimated by a collimator 103 which is arranged laterally surrounding the LED 101. The collimator 103 presents a reflective surface facing the LED 101 and a funnel shape with a cross-sectional area that increases with the distance from the substrate. Hence, the collimator walls leans out from the LED 101.

The collimator 103 is physically bonded to the LED 101 and the substrate 102 by means of a transparent cured bonding material 104, such as a glue.

To preserve the etendue of the light from the LED as much as possible, it is essential that the walls of the collimator is located close to the lateral sides of the LED 101. In the preferred embodiment illustrated in FIG. 1, the walls are arranged at a distance of below 100 μm from the lateral surface of the LED.

As is used herein, a light emitting diode or LED refers to any type of light emitting diode known to those skilled in the art, and includes conventional inorganic based LEDs, as well as organic based LEDs (OLEDs) and polymeric based LEDs.

The LED chip is preferably of the “flip-chip” type where both leads are positioned on the same side of the chip. This design facilitates the arrangement of the wavelength converting body on the light emitting surface of the device. However, also other types of LED chips are contemplated for use in the present invention.

The LEDs for use in the present invention may emit light of any color, from the UV range, over the visible range, to the IR range. However, since wavelength converting materials conventionally converts light by a red shift, it is often desired to use a LED emitting light in the UV/blue range, since such light can be converted into essentially any other color.

The wavelength converting material for use in the present invention is preferably a fluorescent and/or phosphorescent material, which becomes excited by unconverted light and emits light upon relaxation.

In a presently preferred embodiment, the wavelength converting body is shaped into a self-supporting wavelength converting body 105 comprising or consisting of the wavelength converting material.

In one embodiment the self-supporting wavelength converting body may be comprise a pressed ceramic material of essentially wavelength converting material or a dimensionally stable matrix material, such as but not limited to, PMMA (polymethylmethacrylate) or other materials that can be doped with particles and have embedded wavelength converting particles. In another embodiment, the self-supporting wavelength converting body may comprise a ceramic material having a density of more than 97% of the theoretical solid-state density.

Examples of phosphors that may be formed into luminescent ceramic layers include aluminum garnet phosphors with the general formula (Lu_{1-x-y-a-b}YₓGd_{y})₃(Al_{1-z}Ga_{z})₅O₁₂:CeₐPr_{b}, wherein 0<x<1, 0<y<1, 0<z≦0.1, 0<a≦0.2 and 0<b≦0.1, such as Lu₃Al₅O₁₂:Ce³⁺ and Y₃Al₅O₁₂:Ce³⁺ which emit light in the yellow-green range; and (Sr_{1-x-y}BaₓCa_{y})_{2-z}Si₅₋ₐAlₐN₈₋ₐOₐ:Eu_{z}²⁺ wherein 0≦a<5, 0<x≦1, 0≦y≦1, and 0<z≦1, such as Sr₂Si₅N₈:Eu²⁺, which emit light in the red range. Suitable Y₃Al₅O₁₂:Ce³⁺ ceramic slabs may be purchased from Baikowski International Corporation of Charlotte, N.C. Other green, yellow, and red emitting phosphors may also be suitable, including (Sr_{1-a-b}Ca_{b}Ba_{c})SiₓN_{y}O_{z}:Euₐ²⁺ (a=0.002-0.2, b=0.0-0.25, c=0.0-0.25, x=1.5-2.5, y=1.5-2.5, z=1.5-2.5) including, for example, SrSi₂N₂O₂:Eu²⁺; (Sr₁₋ᵤ₋ᵥ₋ₓMgᵤCaᵥBaₓ)(Ga_{2-y-z}Al_{y}In_{z}S₄):Eu²⁺ including, for example, SrGa₂S₄:EU²⁺; Sr₁₋ₓBaₓSiO₄:EU²⁺; and (Ca₁₋ₓSrₓ)S:Eu²⁺ wherein 0<x≦1 including, for example, CaS:Eu²⁺ and SrS:Eu²⁺. Further, materials like SSONe, CeCAS, may also be used.

The self supporting wavelength converting body is typically shaped into a flat plate or a dome shaped body (having a flat surface towards the LED), or any other shape that might suite the application of the device. A flat plate shaped wavelength converting body for use in the present invention typically has a thickness of from 10 to 1000 μm, such as about 100 to 500 μm, for example around 250 μm.

The bonding material 107 for use when optically and physically bonding a self supporting wavelength converting body 105 to an LED is preferably essentially transmissive, at least for unconverted light of the first wavelength.

Examples of bonding materials that are suitable for use depends on the application, the material of the light emitting surface of the LED, the material of the wavelength converting body and on the temperatures to which the bonding material is to be exposed.

Examples of bonding materials include for example low-melting glass, epoxy materials, transmissive polymers, Cyano-acrylate adhesives, UV-curing adhesives and siloxanes, such as PDMS.

The collimator 103 typically comprises one or more self-supporting wall elements of a highly reflective material, such as a metallic material, typically a metal foil, such as of silver, gold, aluminum, titanium, etc.

One example of such a highly reflective material is Miro® from Alanod.

Preferably, the wall-element(s) is(are) thin walls, typically having a thickness of about 100 to 500 μm, or a solid body with an internal reflective chamber.

The height of the collimator and the angle formed by the collimator inner walls to the normal of the substrate depends on the application and the desired degree of collimation of light.

The wall elements may be straight or curved, forming either a V-shaped or U-shaped collimator. The collimator reduces the angles of the source and mix the light at the output window to a homogenous light distribution. In projection display applications, the output window can be imaged with a expander lens and a field lens directly onto the display, where normally mixing rods, integrators or other homogenizers are needed.

Typically, the height of the collimator (counted from the substrate surface is about 5 to 15 mm.

Typically, the angle formed by the collimator inner walls to the normal of the substrate is 5 to 15°.

The collimator 103 is physically bonded to the LED 101 and the substrate 102 by means of a transparent bonding material 104. The bonding material 104 is optically transmissive to aid in outcoupling of light generated in the LED-chip.

The bonding material 104 is preferably a cured, essentially rigid and non-flexible, material formed by in situ-hardening, such as curing, of a precursor material. Examples of bonding materials for use in the present invention include silicon based materials, such as Silicone-material (for example PDMS), and epoxy materials, e.g. Shin-etsu.

Further, the bonding material 104 may encapsulate the LED 101 and optionally, and if present, the wavelength converting plate 105, so as to protect this assembly from external forces, like impact and scratching.

According to the present invention, a light emitting device 100 can be manufactured as described below.

A LED 101, optionally provided with a wavelength converting body 105 as described above, is arranged on a substrate 102.

The collimator 103 is then arranged on the substrate, surrounding the lateral sides of the LED, by the use of a bonding material. The collimator 103 may be a preformed, or alternatively the collimator 103 is formed on the substrate 102 by placing two or more wall elements to collectively form the collimator. The collimator is arranged on the substrate before, after or simultaneously with deposition of the bonding material precursor. The bonding material precursor is deposited so that it is in contact with the LED 101, the substrate 102 and the collimator 103.

Thereafter, the bonding material precursor material is hardened, such as cured, into a bonding material 104 physically bonding the collimator 103 to the substrate and physically and optically bonding the collimator 103 to the LED 101. Optionally, the bonding material is also in contact with the wavelength converting body 105.

The person skilled in the art realizes that the present invention by no means is limited to the preferred embodiments described above. On the contrary, many modifications and variations are possible within the scope of the appended claims. For example, more than one, such as two or more, light emitting diodes may be arranged within one and the same collimating structure. Further, more than one, such as two or more, light emitting diodes may be bonded to one and the same self-supporting wavelength converting body. Further, is should be noted that even though the above description mainly refers to the wavelength converting material contained in a self-supporting wavelength converting body, the present invention is not limited to this, and the wavelength converting material may for example be spray deposited as a powder on the light emitting surface of the LED.

1. A method for the manufacture of a light emitting device, comprising the steps of:
providing a substrate on which at least one light emitting diode is arranged;
arranging a collimator at least partly laterally surrounding said at least one light emitting diode and formed by at least one self-supporting wall element with a material thickness in the range of 100 to 500 μm by bonding said collimator to said at least one light emitting diode and/or said substrate using a transmissive bonding material.

2. A method according to claim 1, wherein a self-supporting wavelength converting element is optically and physically bonded to a light emitting surface of said at least one light emitting diode.

3. A method according to claim 1, wherein the step of bonding said collimator to said at least one light emitting diode and/or said substrate comprises arranging a bonding material precursor and hardening said material precursor to form a bonding material.

4. A method according to claim 1, wherein said collimator is arranged at a distance of from 10 to 200 μm, in the plane of said substrate, from said at least one light emitting diode.

5. A method according to claim 1, wherein said collimator is formed from a metallic material.

6. (canceled)

7. A light emitting device (100) comprising
at least one light emitting diode arranged on a substrate and
a collimator at least partly laterally surrounding said at least one light emitting diode for collimating light emitted by said at least one light emitting diode, said collimator comprising at least one self-supporting wall element with a material thickness in the range of 100 to 500 μm bonded to said substrate and to said at least one light emitting diode by means of a first transmissive bonding material.

8. A light emitting device according to claim 7, further comprising a self-supporting wavelength converting element optically and physically bonded to a light emitting surface of said at least one light emitting diode.

9. A light emitting device according to claim 7, wherein said collimator is formed by metallic material.

10. A light emitting device according to claim 7, wherein a distance, in the plane of said substrate, between said collimator and said at least one light emitting diode is in the range of from 10 to 100 μm.

11. (canceled)

12. A light emitting device according to claim 7, wherein said collimator is funnel-shaped, presenting a cross-sectional area that gradually increases with the distance, along the normal to said substrate, from said substrate.
